(19) United States
(12) Patent Application Publication
(10) Pub. No.: US 2026/0018437 A1
(43) Pub. Date: Jan. 15, 2026

(54) CHAMBER BODY WITH TRENCH FOR RF TRANSMISSION LINES

(71) Applicant: Applied Materials, Inc., Santa Clara, CA (US)

(72) Inventors: Edward P. HAMMOND, IV, Hillsborough, CA (US); David COUMOU, Santa Clara, CA (US); Dmitry A. DZILNO, Sunnyvale, CA (US)

(21) Appl. No.: 18/767,349

(22) Filed: Jul. 9, 2024

(51) Int. Cl. H01L 21/67; H01J 37/32

(52) U.S. Cl. CPC H10P 72/0462; H01J 37/32183; H01J 37/32577; H01J 37/32899

(57) ABSTRACT

A wafer processing system is provided. In one aspect, the wafer processing system includes a chamber body arranged to support a plurality of process chambers. The chamber body defines at least a portion of a trench formed within the chamber body. The wafer processing system also includes transmission lines disposed within the trench to electrically couple an output of a power supply with respective ones of a plurality of antennas disposed within respective ones of the plurality of process chambers.

### BACKGROUND

### Field

Embodiments of the present disclosure generally relate to semiconductor wafer processing systems.

### Description of the Related Art

Semiconductor wafer processing systems (e.g., cluster tools) are used in the manufacturing of semiconductor devices on substrates. These systems move or convey wafers between different process chambers. Different processes may be performed on the wafers in the process chambers. For example, different layers or features may be formed on the wafers in the process chambers. To perform certain processes, radio frequency (RF) power may be delivered to an electrode or coil disposed within a process chamber, e.g., to generate a plasma in the process chamber to improve one or more characteristics of a process being performed therein.

There are existing solutions for delivering RF power to the process chambers. However, it has been challenging to design RF power transmission solutions that account for the serviceability, organization, safety, and electrical phase matching of the RF power to power-consuming complex loads of the process chambers. Accordingly, there is a need in the art for a wafer processing system having improved RF power transmission features.

### SUMMARY

The present disclosure provides a semiconductor wafer processing system that includes a chamber body defining a trench in which transmission lines pass through.

In one embodiment, a wafer processing system is provided. The wafer processing system includes a chamber body arranged to support a plurality of process chambers. The chamber body defines a portion of a trench formed within the chamber body. The wafer processing system also includes transmission lines disposed within the trench to electrically couple an output of a power supply with respective ones of a plurality of antennas disposed within respective ones of the plurality of process chambers.

In another embodiment, a wafer processing system is provided. The wafer processing system includes a chamber body defining a trench and a reference plane. The wafer processing system also includes a plurality of process chambers each held by the chamber body, the plurality of process chambers including a first process chamber, a second process chamber, a third process chamber, and a fourth process chamber, with the first and second process chambers being arranged on a first side of the reference plane and the third and fourth process chambers being arranged on a second side of the reference plane. Further, the wafer processing system includes a plurality of transmission lines passing through the trench, the plurality of transmission lines including a first transmission line, a second transmission line, a third transmission line, and a fourth transmission line electrically coupled with the first, second, third, and fourth process chambers, respectively. The first, second, third, and fourth transmission lines are arranged to have substantial parity within the trench.

In yet another embodiment, a wafer processing system is provided. The wafer processing system includes a chamber body defining a trench having an ingress channel, first and second delivery channels in communication with, and extending in opposite directions from, the ingress channel, and first and second egress channels in communication with the first and second delivery channels, respectively. Also, the wafer processing system includes a plurality of process chambers each held by the chamber body. Further, the wafer processing system includes a plurality of transmission lines passing through the trench and being electrically coupled with respective ones of the plurality of process chambers. Each one of the plurality of transmission lines passes through the ingress channel, at least two transmission lines of the plurality of transmission lines pass through the first delivery channel, at least two transmission lines of the plurality of transmission lines pass through the second delivery channel, the at least two transmission lines passing through the first delivery channel exit the trench through the first egress channel, and the at least two transmission lines passing through the second delivery channel exit the trench through the second egress channel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates an example wafer processing system, according to one or more embodiments of the disclosure.

FIG. 2 illustrates an example power delivery circuit of the wafer processing system of FIG. 1, according to one or more embodiments of the disclosure.

FIG. 3 illustrates a perspective view of a portion of the wafer processing system of FIG. 1, and more specifically, a view of a chamber body thereof, according to one or more embodiments of the disclosure.

FIG. 4 illustrates a schematic side view of the chamber body of FIG. 3, according to one or more embodiments of the disclosure.

FIG. 5 illustrates a close-up, cross-sectional view of a trench defined by the chamber body of FIG. 3, according to one or more embodiments of the disclosure.

FIG. 6 illustrates a schematic top plan view of a chamber body for a wafer processing system, according to one example embodiment of the present disclosure.

FIG. 7 illustrates a schematic perspective view of a chamber body for a wafer processing system, according to one example embodiment of the present disclosure.

FIG. 8 illustrates a schematic side view of a chamber body for a wafer processing system, according to one example embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally provides a semiconductor wafer processing system adapted to process substrates. In one aspect, a wafer processing system can include a chamber body arranged to support multiple process chambers each having one or more power-consuming complex loads (e.g., a plasma formed during processing). Radio frequency (RF) power may be delivered to the loads of the process chambers by way of respective transmission lines. In some embodiments, the transmission lines are used to evenly distribute RF power provided from a single RF source. The chamber body can define a trench through which the transmission lines pass through. The transmission lines can be electrically coupled with an RF power splitting circuit (e.g., a splitter circuit) and can pass through the trench to a power delivery region of the chamber body, or rather, a location where the transmission lines can be electrically coupled with the power-consuming loads of the process chambers.

Passing the transmission lines through the trench of the chamber body can provide certain advantages, benefits, and/or technical effects. For instance, passing the transmission lines through the trench defined within the chamber body can keep the transmission lines out of the way from nearby components, systems, and/or personnel, which can improve the safety and organization of the system. In some embodiments, dividers can be arranged between transmission lines within the trench to prevent or reduce crosstalk between them. In some embodiments, servicing of the transmission lines can also be made readily accessible by way of an access panel that can be placed over the chamber body to enclose the trench with the transmission lines arranged therein. The access panel can be removed to service the transmission lines. The access panel can include a conductive material (e.g., metal) and be in electrical communication with the chamber body and a ground coupled thereto. Moreover, in at least some embodiments, by passing the transmission lines through the trench, the chamber body can provide an electrical ground for the transmission lines. Further, in some embodiments, advantageously, the trench can be defined and the transmission lines can be arranged within the trench in such a way that the transmission lines have substantial parity within the trench, which facilitates the transmission lines having a same or substantially the same signal path length (or electrical length) traveling through the trench. Accordingly, the one or more power-consuming loads formed within the respective process chambers can receive portions of RF power that are better matched in electrical phase and in the amount of delivered forward RF power and a minimum of reflected RF power. In addition, in some embodiments, the transmission lines can be configured to correspond to a same target characteristic impedance. Example embodiments are provided below.

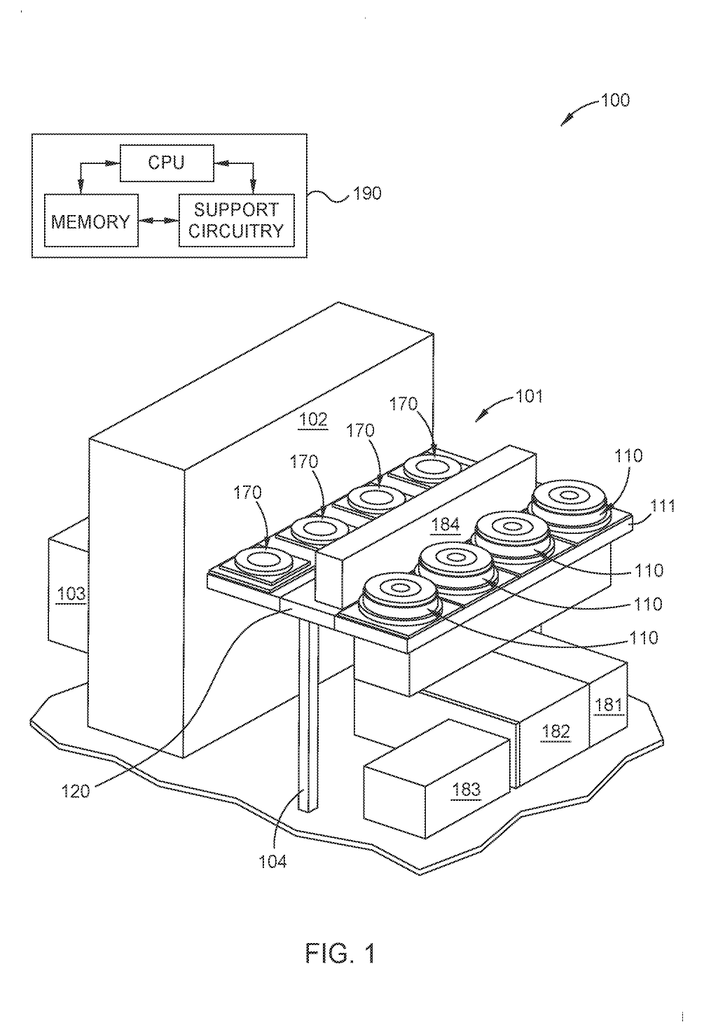

FIG. 1 illustrates an example wafer processing system 100. The system 100 includes a factory interface 102 and at least one processing mainframe 101.

The processing mainframe 101 includes multiple process chambers 110, a swapper assembly 120, multiple load locks 170, and a controller 190. The processing mainframe 101 may include any number of process chambers 110 and load locks 170. For example, the processing mainframe 101 may include two, three, four, and/or more than four process chambers 110 and load locks 170. The load locks 170 and process chambers 110 can be grouped in pairs, with each grouping having one load dock 170 opposing a corresponding process chamber 110. The swapper assembly 120 is located between the process chambers 110 and the load locks 170. The swapper assembly 120 includes a swapper for each pair of the process chambers 110 and load locks 170, and each swapper is used to move substrates or wafers between the corresponding process chamber 110 and load dock 170. The processing mainframe 101 may be structurally supported in a position relative to the factory interface 102 by one or more supports 104 (e.g., frames). For example, the supports 104 may support the weight of the processing mainframe 101.

As shown in FIG. 1, the processing mainframe 101 includes four pairs of process chambers 110 and load locks 170. In some embodiments, the processing mainframe 101 may have only one process chamber 110 and load dock 170. In some embodiments, the processing mainframe 101 may have two or three process chambers 110 and load locks 170. In some embodiments, the processing mainframe 101 may have more than four process chambers 110 and load locks 170. The process chambers 110 are held by a chamber body 111. In some embodiments, the chamber body 111 can define cavities in which respective ones of the process chambers 110 are disposed.

The process chambers 110 include a substrate support (e.g., pedestal, platen) and a processing kit and source assembly that process a wafer within the process chambers 110. The process chambers 110 may perform any number of processes such as preclean, chemical vapor deposition (CVD), plasma enhanced chemical vapor deposition (PECVD), physical vapor deposition (PVD), atomic layer deposition (ALD), decoupled plasma nitridation (DPN), rapid thermal processing (RTP), ashing, annealing, and etching, or any process utilized in electronic device fabrication. In one embodiment, the processing sequence is adapted to form a high-K capacitor structure, where process chambers 110 may be a DPN chamber, a CVD chamber capable of depositing poly-silicon, and/or a MCVD chamber capable of depositing titanium, tungsten, tantalum, platinum, or ruthenium.

The factory interface 102 may be coupled to one or more front opening unified pods (FOUPs) 103. FOUPs 103 may each be a container having a stationary cassette therein for holding multiple wafers. FOUPs 103 may each have a front opening interface configured to be used with factory interface 102. Factory interface 102 may have a buffer chamber (not shown) and one or more robot assemblies to transfer wafers via linear, rotational, and/or vertical movement between FOUPs 103 and the load locks 170. The factory interface 102 may include a set of FOUPs 103 and corresponding one or more robot assemblies for each processing mainframe 101.

In some embodiments, the process chambers 110 are part of a monolithic structure (e.g., mainframe), such as sharing a common housing. In some embodiments, the swapper assembly 120 and the load locks 170 may each be part of a separate monolithic structure. Thus, in this case, the processing mainframe 101 may be formed by connecting a monolithic structure including the process chambers 110 to one side of the monolithic structure of the swapper assembly 120 and then also connecting a monolithic structure including the load locks 170 to the other side of the monolithic structure including the swapper assembly 120. Assembling the system 100 from monolithic structures, each including multiple components, such as process chambers 110, load locks 170, or swapper assembly 120, decreases manufacturing and assembly costs and reduces the number of leak points. In some other embodiments, the process chambers 110, the swapper assembly 120 and the load locks 170 may each be part of a single monolithic structure that is used to support and provide a positional reference for the mounting and aligning of the various components to each other and to the monolithic structure.

The system 100 may also include a pumping system 181, a gas panel 182, a power supply 183, and an electronics module 184. The pumping system 181, gas panel 182, and power supply 183 are shown disposed underneath the processing mainframe 101. The pumping system 181 creates and/or maintains a pressure within each process chamber 110. For example, the pumping system 181 may include a vacuum pump that evacuates the process chambers 110. The gas panel 182 may supply one or more gases used to process a wafer in a process chamber 110. The power supply 183 may be a power source (e.g., an AC power source or a DC power source) that powers electrical equipment of the system 100, such as operating equipment in the process chambers 110 (e.g., the source assemblies). The power supply 183 may also include an RF power supply that supplies RF power to the process chambers 110 to capacitively couple RF power to form a plasma within a processing region of the process chamber 110 by use of, for example a showerhead or an electrode within an electrostatic chuck, or inductively couple RF power to form a plasma within the processing region of the process chamber 110 by use of a coil. The electronics module 184 may include electronics used to monitor and control the system 100. The electronics module 184 may be in communication with the controller 190.

The pumping system 181 may create and maintain a pressure within the load locks 170 (e.g., evacuating each load dock 170). The pumping system 181 may also create and maintain a pressure within the swapper assembly 120 (e.g., evacuating the swapper assembly 120). The system 100 may include a separate pumping system 181 for each of the process chambers 110, the swapper assembly 120, and the load locks 170.

In some embodiments of the system 100, the process chambers 110 are isolated from each other, and thus do not share resources other than a power delivery circuit, which will be discussed further below. However, in some other embodiments, the process chambers 110 are partially isolated from each other, and in this case, may additionally share some resources other than a power delivery circuit. In one example, the process chambers 110 share the pumping system 181 and the gas panel 182.

The controller 190 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, and the like, and combinations thereof coupled to the various components of the system 100, to facilitate control of the system 100. For example, in one or more embodiments the CPU is one of any form of general purpose computer processor used in an industrial setting, such as a programmable logic controller (PLC), for controlling the RF power directed to different process chambers 110. The memory, coupled to the CPU, is non-transitory and is one or more of readily available memory such as random access memory (RAM), read only memory (ROM), floppy disk drive, hard disk, or any other form of digital storage, local or remote.

The CPU is any electronic circuitry, including, but not limited to one or a combination of microprocessors, microcontrollers, application specific integrated circuits (ASIC), application specific instruction set processor (ASIP), and/or state machines, that communicatively couples to the memory and controls the operation of the system 100. The CPU may be 8-bit, 16-bit, 32-bit, 64-bit or of any other suitable architecture. The CPU may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The CPU may include other hardware that operates software to control and process information. The CPU executes software stored on the memory to perform any of the functions described herein. The CPU is not limited to a single processing device and may encompass multiple processing devices contained in the same device or computer or distributed across multiple devices or computers. The CPU is considered to perform a set of functions or actions if the multiple processing devices collectively perform the set of functions or actions, even if different processing devices perform different functions or actions in the set.

The memory may store, either permanently or temporarily, data, operational software, or other information for the CPU. The memory may include any one or a combination of volatile or non-volatile local or remote devices suitable for storing information. For example, the memory may include random access memory (RAM), read only memory (ROM), magnetic storage devices, optical storage devices, or any other suitable information storage device or a combination of these devices. The software represents any suitable set of instructions, logic, or code embodied in a computer-readable storage medium. For example, the software may be embodied in the memory, a disk, a CD, or a flash drive. In particular embodiments, the software may include an application executable by the CPU to perform one or more of the functions described herein. The memory is not limited to a single memory and may encompass multiple memories contained in the same device or computer or distributed across multiple devices or computers. The memory is considered to store a set of data, operational software, or information if the multiple memories collectively store the set of data, operational software, or information, even if different memories store different portions of the data, operational software, or information in the set.

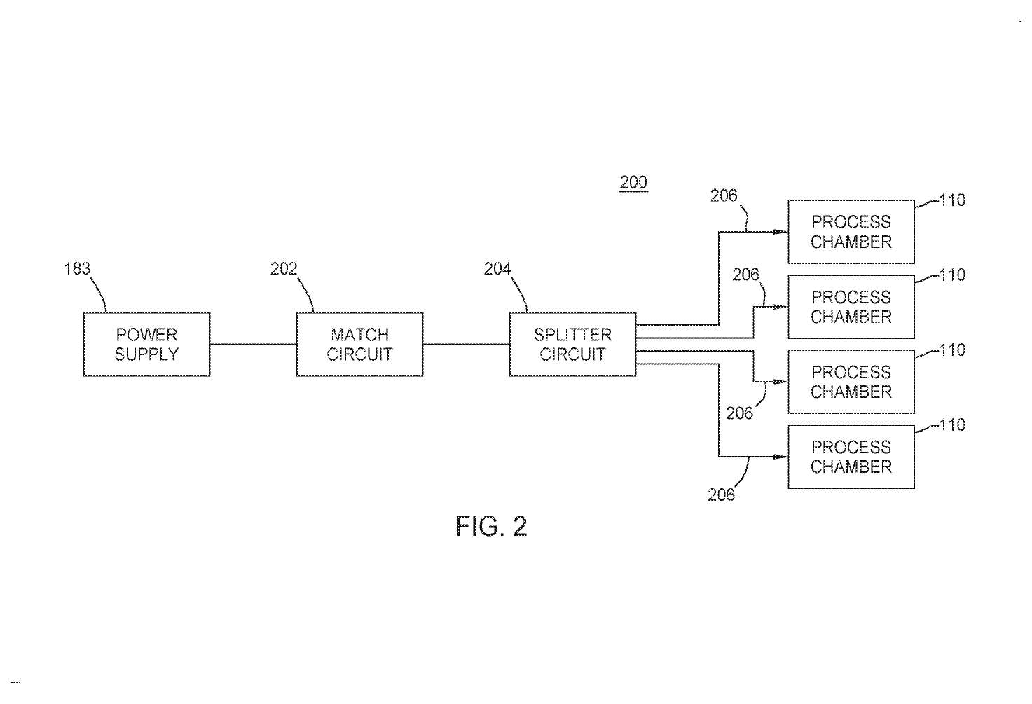

FIG. 2 illustrates an example power delivery circuit 200 of the wafer processing system 100 of FIG. 1. As shown in FIG. 2, the power delivery circuit 200 includes the power supply 183, a match circuit 202, and a splitter circuit 204. Generally, the power delivery circuit 200 produces RF power and directs that RF power to multiple process chambers 110 of the wafer processing system 100.

The power supply 183 generates an electrical current and directs that electrical current to the match circuit 202. The electrical current may be an RF electrical current. In this manner, the power supply 183 produces RF power for forming a plasma in the process chambers 110 of the system 100. The power supply 183 directs the electrical current to the match circuit 202.

The match circuit 202 may present an impedance to the power supply 183. The match circuit 202 includes at least one variable electrical component (e.g., a variable capacitor) that is adjusted (e.g., using control signals from the controller 190) to adjust the impedance that the match circuit 202 presents to the power supply 183. For example, by adjusting a capacitance of a variable capacitor in the match circuit 202, the impedance (e.g., 50 Ω) presented by the match circuit 202 to the power supply 183 changes. In some embodiments, the impedance presented by the match circuit 202 may be selected to improve power transfer or to reduce signal reflection (e.g., of the RF current from the power supply 183). The match circuit 202 receives the electrical current from the power supply 183 and directs the electrical current to the splitter circuit 204.

The splitter circuit 204 directs portions of the electrical current from the match circuit 202 to different process chambers 110 of the system 100 by way of respective transmission lines 206. The splitter circuit 204 includes legs with variable electrical components (e.g., variable capacitors and/or inductors). These legs direct portions of the electrical current to the different process chambers 110. The amount of electrical current directed by a leg to a process chamber 110 may be adjusted by adjusting these variable electrical components (e.g., using control signals from the controller 190).

In some embodiments, the power delivery circuit 200 includes voltage and/or current sensors. For example, one or more legs of the splitter circuit 204 may include a sensor that detects the electrical current directed by the legs to process chambers 110. The controller 190 may use the information from the sensors to determine how to adjust the variable electrical components in one or more of the legs of the splitter circuit 204.

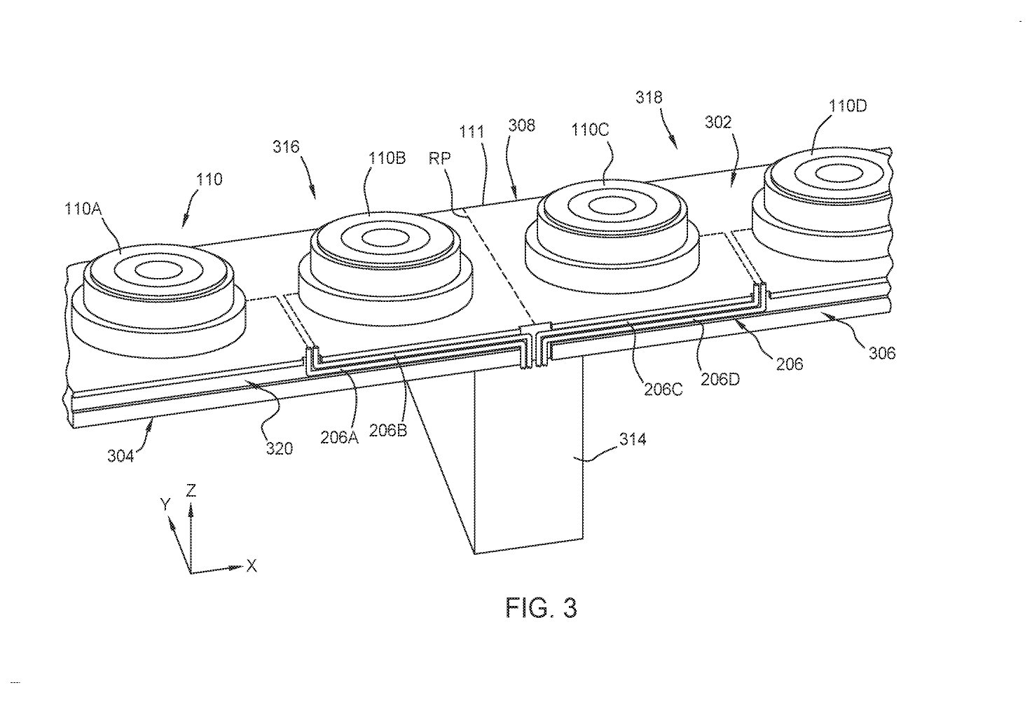

FIG. 3 illustrates a perspective view of a portion of the wafer processing system 100 of FIG. 1, and more specifically, FIG. 3 depicts a close-up view of the chamber body 111 thereof. For reference, the wafer processing system 100 defines a first direction X, a second direction Y, and a third direction Z, which are mutually perpendicular to one another. In some embodiments, the first direction X may be a lateral direction, the second direction Y may be a transverse direction, and the third direction Z may be a vertical direction. Also, the chamber body 111 can define a reference plane RP, which can be a central or sagittal plane of the chamber body 111 in some embodiments. The reference plane RP extends in a plane orthogonal to the first direction X. In some embodiments, the chamber body 111 can be formed of aluminum, other metallic materials, or some other electrically conductive material.

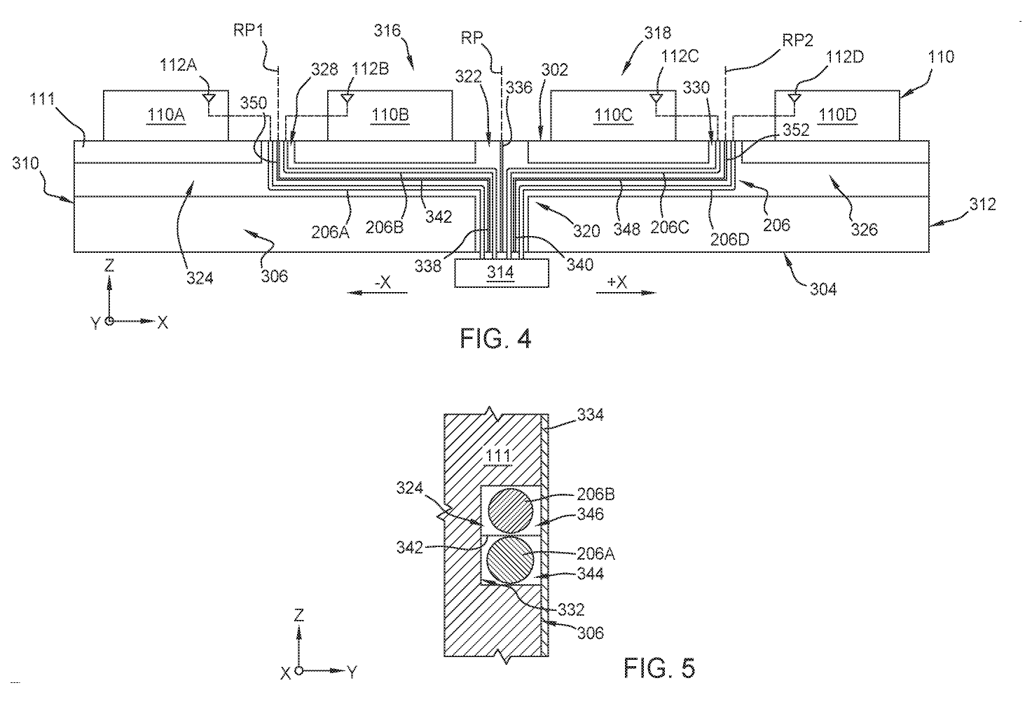

The chamber body 111 has a top surface 302, a bottom surface 304, and opposing sidewall surfaces, including a first sidewall surface 306 and a second sidewall surface 308. The chamber body 111 also has first and second end surfaces 310, 312 (FIG. 4) arranged at respective ends of the chamber body 111. The top surface 302 and the bottom surface 304 are spaced from one another, e.g., along the third direction Z. The first and second sidewall surfaces 306, 308 are spaced from one another, e.g., along the second direction Y, and extend between and connect the top and bottom surfaces 302, 304. A housing 314 enclosing the match circuit 202 (FIG. 2) and the splitter circuit 204 (FIG. 2) may be disposed underneath the chamber body 111, e.g., beneath the bottom surface 304 thereof. In other embodiments, the match circuit 202 and the splitter circuit 204 may be disposed in separate housings.

The chamber body 111 defines a plurality of cavities in which respective process chambers 110 may be disposed. In the depicted embodiment of FIG. 3, the chamber body 111 defines four (4) cavities in which respective process chambers 110 are disposed, including a first process chamber 110A, a second process chamber 110B, a third process chamber 110C, and a fourth process chamber 110D. In this regard, the chamber body 111 supports the first, second, third, and fourth process chamber 110A-110D. While four (4) cavities and four (4) process chambers are depicted in FIG. 3, the chamber body 111 may define more or less than four (4) cavities and have more or less than four (4) process chambers in other embodiments. The cavities may be counterbored holes, but in other embodiments, the cavities may have other configurations. In at least some example embodiments, the chamber body 111 may define the cavities such that they are equidistantly spaced from one another, e.g., along the first direction X. In this way, the process chambers 110A-110D can also be equidistantly spaced from one another, e.g., along the first direction X. Moreover, in illustrated embodiment of FIG. 3, the first process chamber 110A and the second process chamber 110B are arranged on a first side 316 of the reference plane RP and the third process chamber 110C and the fourth process chamber 110D are arranged on a second side 318 of the reference plane RP.

The chamber body 111 includes features that facilitate the delivery of RF power to the process chambers 110 (FIG. 1), e.g., to power electrodes. In the illustrated embodiment of FIG. 3, the first sidewall surface 306 of the chamber body 111 defines a trench 320 in which the transmission lines 206 are arranged. The transmission lines 206 pass through the trench 320 to electrically couple the power supply 183 with their associated process chambers 110, or more specifically in this example embodiment, to electrically connect the splitter circuit 204 with the process chambers 110 so that electrical power can be provided to the process chambers 110. Accordingly, the trench 320 generally provides a passage for the transmission lines 206 to travel from the housing 314 to the process chambers 110. The trench 320 can be carved into the chamber body 111 by a machining process, formed during an additive manufacturing build of the chamber body 111, or in some other manner.

For the depicted embodiment of FIG. 3, the wafer processing system 100 includes four (4) transmission lines passing through the trench 320, including a first transmission line 206A, a second transmission line 206B, a third transmission line 206C, and a fourth transmission line 206D. The first transmission line 206A passes through the trench 320 to electrically couple the power supply 183 (FIG. 1) with the first process chamber 110A, the second transmission line 206B passes through the trench 320 to electrically couple the power supply 183 with the second process chamber 110B, the third transmission line 206C passes through the trench 320 to electrically couple the power supply 183 with the third process chamber 110C, and the fourth transmission line 206D passes through the trench 320 to electrically couple the power supply 183 with the fourth process chamber 110D. The transmission lines can include a rigid, semi-rigid or flexible coaxial cable that is configured to deliver RF power from the RF source to each of the process chambers. Rigid transmission lines can tolerate higher RF currents and dissipate less power than other transmission line types. Accordingly, rigid transmission lines may be beneficial for higher RF current applications. In other embodiments, the transmission lines can be implemented as cables, particularly in embodiments where the electrode might be moving, such as where RF power is applied to a mesh in the pedestal heater, which moves between a release position (where wafers are placed on or removed from lift pins) and a process position (where RF power is applied to generate plasma).

With reference to FIG. 4, a schematic side view of the chamber body 111 is depicted. As shown, the trench 320 has an ingress channel 322, first and second delivery channels 324, 326, and first and second egress channels 328, 330. The first and second delivery channels 324, 326 are both in communication with the ingress channel 322 and extend from the ingress channel 322 in opposite directions, e.g., in opposite directions along the first direction X, with the first delivery channel 324 extending along a negative first direction –X and the second delivery channel 326 extending along a positive first direction +X. The first and second egress channels 328, 330 are in communication with the first delivery channel 324 and the second delivery channel 326, respectively.

The ingress channel 322 extends from the bottom surface 304 toward the top surface 302, e.g., along the third direction Z, so as to communicate with the first and second delivery channels 324, 326. In some embodiments, the ingress channel 322 can extend from the bottom surface 304 to the top surface 302, e.g., along the third direction Z. In other embodiments, the ingress channel 322 can extend from the bottom surface 304 to the top ends of the first and second delivery channels 324, 326, e.g., along the third direction Z. The transmission lines 206 enter the trench 320 through the ingress channel 322 and initially extend lengthwise along the third direction Z. Accordingly, the ingress channel 322 has a width (e.g., along the first direction X) arranged to accommodate the first, second, third, and fourth transmission lines 206A-206D. In some embodiments, the width of the ingress channel 322 can be sized to accommodate other numbers of transmission lines 206, such as eight (8) transmission lines 20 in embodiments in which the chamber body 111 supports eight (8) process chambers. In at least some embodiments, the width of the ingress channel 322 can be sized to accommodate each one of the transmission lines 206 traveling between a downstream circuit (e.g., the splitter circuit 204 of FIG. 2) and the process chambers 110.

After the transmission lines 206 enter the trench 320 through the ingress channel 322 and initially extend lengthwise along the third direction Z, the first and second transmission lines 206A, 206B turn and enter into the first delivery channel 324 while the third and fourth transmission lines 206C, 206D turn and enter into the second delivery channel 326. In the depicted embodiment of FIG. 4, the first and second transmission lines 206A, 206B extend from the ingress channel 322 through the first delivery channel 324 to the left along the negative first direction –X and the third and fourth transmission lines 206C, 206D extend from the ingress channel 322 through the second delivery channel 326 to the right along the positive first direction +X. In this way, the first and second transmission lines 206A, 206B extend from the ingress channel 322 in an opposite direction than the third and fourth transmission lines 206C, 206D.

The first and second egress channels 328, 330 each extend from the top surface 302 toward the bottom surface 304, e.g., along the third direction Z, so as to communicate with the first and second delivery channels 324, 326. In some embodiments, the first and second egress channels 328, 330 may each extend from the top surface 302 until they are in communication with the first and second delivery channels 324, 326, respectively, e.g., as shown in FIG. 4. Accordingly, in such embodiments, the first and second egress channels 328, 330 do not extend to the bottom surface 304. In other embodiments, however, the first and second egress channels 328, 330 may each extend from the top surface 302 to the bottom surface 304.

After the transmission lines 206 travel along the first and second delivery channels 324, 326, e.g., in opposite directions along the first direction X, the first and second transmission lines 206A, 206B turn and enter into the first egress channel 328 while the third and fourth transmission lines 206C, 206D turn and enter into the second egress channel 330. The first and second transmission lines 206A, 206B can exit the trench 320 through the first egress channel 328 and can electrically connect with one or more antenna (e.g., electrodes or coils) within their respective first and second process chambers 110A, 110B. Similarly, the third and fourth transmission lines 206C, 206D can exit the trench 320 through the second egress channel 330 and can electrically connect with one or more antenna (e.g., electrodes or coils) within their respective third and fourth process chambers 110C, 110D. Accordingly, in the depicted embodiment of FIG. 4, the transmission lines 206A-206D disposed within the trench 320 electrically couple an output of the power supply 183 (FIG. 2) with respective ones of a plurality of antennas 112A, 112B, 112C, 112D disposed within respective ones of the plurality of process chambers 110A, 110B, 110C, 110D. That is, the first transmission line 206A electrically couples the output of the power supply 183 with the antenna 112A disposed within the first process chamber 110A, the second transmission line 206B electrically couples the output of the power supply 183 with the antenna 112B disposed within the second process chamber 110B, the third transmission line 206C electrically couples the output of the power supply 183 with the antenna 112C disposed within the third process chamber 110C, and the fourth transmission line 206D electrically couples the output of the power supply 183 with the antenna 112D disposed within the fourth process chamber 110D.

In some embodiments, one or more of the transmission lines 206 can include one or more elbow fittings. The elbow fittings can be arranged at the turns of the transmission lines 206, for example. For instance, by way of example, the first transmission line 206A can include one elbow fitting to transition the first transmission line 206A from the ingress channel 322 to the first delivery channel 324, e.g., at a first ninety degree (90°) turn, and another elbow fitting to transition the first transmission line 206A from the first delivery channel 324 to the first egress channel 328, e.g., at a second ninety degree (90°) turn. The second, third, and fourth transmission lines 206B, 206C, 206D can be similarly outfitted.

In some further embodiments, the transmission lines 206 can be partitioned or divided into separate sections within the trench 320, e.g., to eliminate or reduce crosstalk between the lines. As illustrated in FIG. 4, a plurality of dividers separate the trench 320, or specifically the various channels thereof, into different sections. The dividers can be formed of a metallic material (e.g., aluminum), for example. In at least some example embodiments, the dividers arranged within the trench 320 can be connected with the chamber body 111, e.g., to a recessed surface 332 (FIG. 5) thereof. For instance, the dividers can be cantilevered from the recessed surface 332 and can extend the transverse length of the trench 320, e.g., along the second direction Y so that the dividers are substantially even with the first sidewall surface 306 along the second direction Y. In some other embodiments, the dividers can be coupled with an access panel 334 (FIG. 5) that is placed over the first sidewall surface 306 to enclose the trench 320.

For the depicted embodiment of FIG. 4, an ingress channel divider 336 is arranged in the ingress channel 322 of the trench 320 and separates the first and second transmission lines 206A, 206B from the third and fourth transmission lines 206C, 206D. In at least some embodiments, the ingress channel divider 336 can be arranged coplanar with the reference plane RP, or at least aligned in part with the reference plane RP along the first direction X. The ingress channel divider 336 can extend from the bottom surface 304 to the top surface 302, for example. Further, a first ingress divider 338 is arranged in the ingress channel 322 of the trench 320 and separates the first and second transmission lines 206A, 206B along at least a portion of the ingress channel 322. Similarly, a second ingress divider 340 is arranged in the ingress channel 322 of the trench 320 and separates the third and fourth transmission lines 206C, 206D along at least a portion of the ingress channel 322. Accordingly, in such embodiments, each transmission line 206 is separated by a divider in the ingress channel 322.

In addition, as depicted in FIG. 4, a first delivery channel divider 342 is arranged in the first delivery channel 324 of the trench 320 and separates the first and second transmission lines 206A, 206B along at least a portion of the first delivery channel 324. The first delivery channel divider 342 can connect to the first ingress divider 338. With brief reference to FIG. 5, FIG. 5 is a close-up, cross-sectional view of the first delivery channel divider 342 arranged within the trench 320 and separating the trench 320, or rather the first delivery channel 324 thereof, into a first section 344 and a second section 346 (or first and second environments). The first transmission line 206A and the second transmission line 206B are disposed in the first and second sections 344, 346, respectively. The first delivery channel 324 is shown extending between the recessed surface 332 and the access panel 334, e.g., along the second direction Y.

Returning to FIG. 4, a second delivery channel divider 348 is arranged in the second delivery channel 326 of the trench 320 and separates the third and fourth transmission lines 206C, 206D along at least a portion of the second delivery channel 326. The second delivery channel divider 348 can connect to the second ingress divider 340.

Further, a first egress divider 350 is arranged in the first egress channel 328 of the trench 320 and separates the first and second transmission lines 206A, 206B along at least a portion of the first egress channel 328. The first egress divider 350 can connect to the first delivery channel divider 342. A second egress divider 352 is arranged in the second egress channel 330 of the trench 320 and separates the third and fourth transmission lines 206C, 206D along at least a portion of the second egress channel 330. The second egress divider 352 can connect to the second delivery channel divider 348.

Accordingly, for the embodiment illustrated in FIG. 4, the transmission lines 206 are separated by dividers along an entirety of their respective travel paths within the trench 320, which may eliminate or reduce crosstalk between the transmission lines 206. By use of the combination of the delivery channel 320, dividers, and access plate each section that contains a transmission line can form a Faraday cage around each transmission line to reduce crosstalk between the transmission lines. In other embodiments, some combination of the disclosed dividers can be implemented. Any combination of the disclosed dividers is contemplated. In yet other embodiments, such as embodiments in which there are more than four (4) transmission lines, additional dividers can be implemented.

In at least some further embodiments, the chamber body 111 can define the trench 320, and the transmission lines 206 can be arranged within the trench 320, so that symmetry or parity of the transmission lines 206 is achieved or substantially achieved. That is, the trench 320 of the chamber body 111 and the transmission lines 206 can be arranged so that each one of the transmission lines 206 has a same or substantially the same signal path length (or electrical length) traveling through the trench 320. This can facilitate a same or substantially the same total signal path length for each of the transmission lines 206 from a downstream circuit (e.g., the splitter circuit 204 of FIG. 2) to each of their respective process chambers 110, which can be beneficial from an electrical phase matching and power delivery perspective. Accordingly, each load, or one or more power-consuming devices of the respective process chambers 110, can be better matched in electrical phase. This can advantageously provide more consistent simultaneous wafer processing between the process chambers 110, among other benefits.

In the illustrated embodiment of FIG. 4, for example, the ingress channel 322 is centered on the reference plane RP, the first egress channel 328 is centered on a first side reference plane RP1, and the second egress channel 330 is centered on a second side reference plane RP2. The first side reference plane RP1 is arranged on the first side 316 of the reference plane RP and equidistant between the first process chamber 110A and the second process chamber 110B. The second side reference plane RP2 is arranged on the second side 318 of the reference plane RP and equidistant between the third process chamber 110C and the fourth process chamber 110D. The first and second side reference planes RP1, RP2 are spaced equidistant from the reference plane RP. Accordingly, the trench 320 is carved or formed into the chamber body 111 so that the transmission lines 206 passing through the trench 320 have substantial parity, or rather, substantially similar signal path lengths through the trench 320, which as noted above, can be beneficial from an electrical phase matching perspective.

In at least some embodiments, the transmission lines 206 can each have a signal path length that is within ten percent (10%) of a target signal path length, with the target signal path length being a desired length of a transmission line passing through the trench 320. In yet other embodiments, the transmission lines 206 can each have a signal path length that is within five percent (5%) of a target signal path length. In further embodiments, the transmission lines 206 can each have a signal path length that is within one percent (1%) of a target signal path length. Accordingly, despite some of the process chambers 110 being positioned further from the downstream circuit (e.g., the splitter circuit 204 of FIG. 2) than others, the transmission lines 206 can be arranged to have parity or substantial parity.

In some aspects, the transmission lines 206 are configured to correspond to a same target characteristic impedance. Generally, the characteristic impedance of a transmission line depends on the dimensions of the transmission line and its proximity to electrical ground. In at least some example aspects, the target characteristic impedance for each of the transmission lines 206 can be between forty and fifty ohms (40 – 50 Ω), including the endpoints. Transmission lines generally include a center conductor and an adjacent ground return. In some embodiments, the transmission lines 206 of the present disclosure include a center conductor (e.g., the circular elements 206A, 206B depicted in FIG. 5), and the trench 320 in the chamber body 111 along with the cover 334 and dividers provide the adjacent ground return. In this regard, the chamber body 111 and, if present, the dividers can provide a ground return for the transmission lines 206.

In the embodiments of FIGS. 3, 4, and 5, the trench 320 is defined by the first sidewall surface 306. However, in other embodiments, the trench 320 can be defined by other surfaces of the chamber body 111. Examples are provided below.

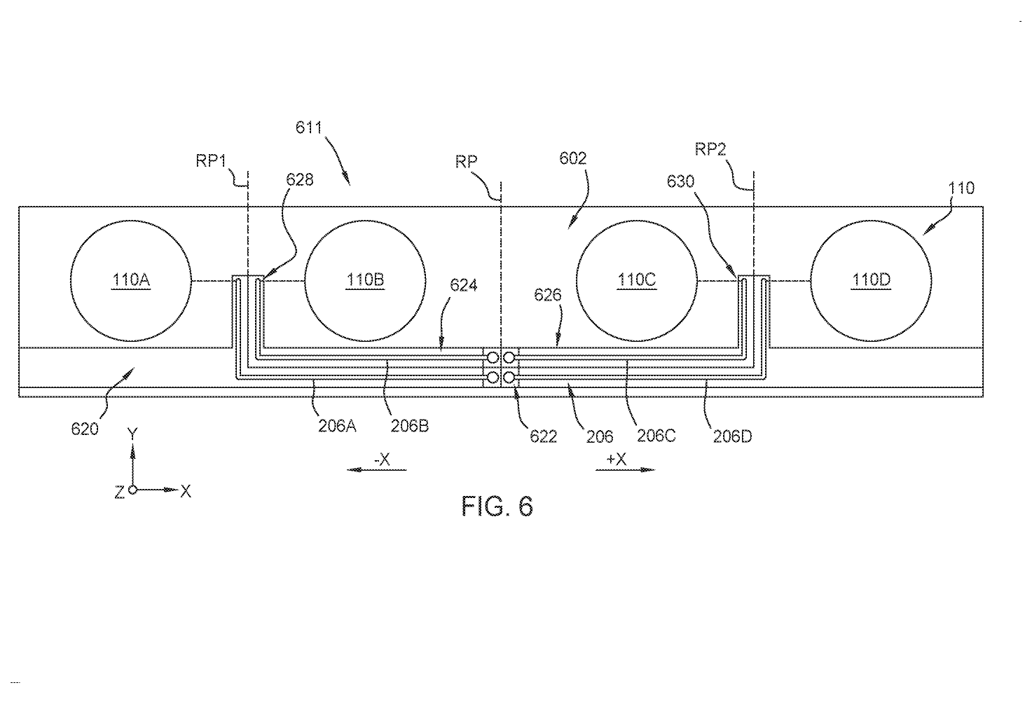

FIG. 6 is a schematic top plan view of a chamber body 611 for a wafer processing system, according to one example embodiment of the present disclosure. In the depicted embodiment of FIG. 6, a trench 620 defined by the chamber body 611 is generally defined by a top surface 602 of the chamber body 611. In particular, the trench 620 includes an ingress channel 622 that is vertically-oriented along the third direction Z and extends from a bottom surface of the chamber body 611 until the ingress channel 622 intersects or is in communication with first and second delivery channels 624, 626 of the trench 620. Accordingly, the transmission lines 206 can be fed from a housing (enclosing the match circuit 202 (FIG. 2) and the splitter circuit 204 (FIG. 2)) arranged beneath the chamber body 611 into the ingress channel 622. The transmission lines 206 can extend lengthwise vertically through the ingress channel 622, as represented by the array of circles in FIG. 6. The first and second delivery channels 624, 626 extend outward from the ingress channel 622 in opposing directions, e.g., along the negative and positive first directions –X, +X. Consequently, the transmission lines 206 can travel lengthwise in opposing directions within their respective first and second delivery channels 624, 626.

The transmission lines 206 can then turn and exit the trench 620 through first and second egress channels 628, 630 arranged in communication with the first and second delivery channels 624, 626, respectively. In some embodiments, the transmission lines 206 can turn and exit the trench 620 from the first and second delivery channels 624, 626; in this manner, the first and second egress channels 628, 630 can be omitted in such embodiments. The first and second delivery channels 624, 626 and the first and second egress channels 628, 630 are recessed with respect to the top surface 602. An access panel can be arranged on the top surface 602 to enclose the trench 620 once the transmission lines 206 are arranged in place within the trench 620. In this example, the trench 620 and the transmission lines 206 can be arranged to have substantially parity or electrical length and can be configured to have a same target characteristic impedance.

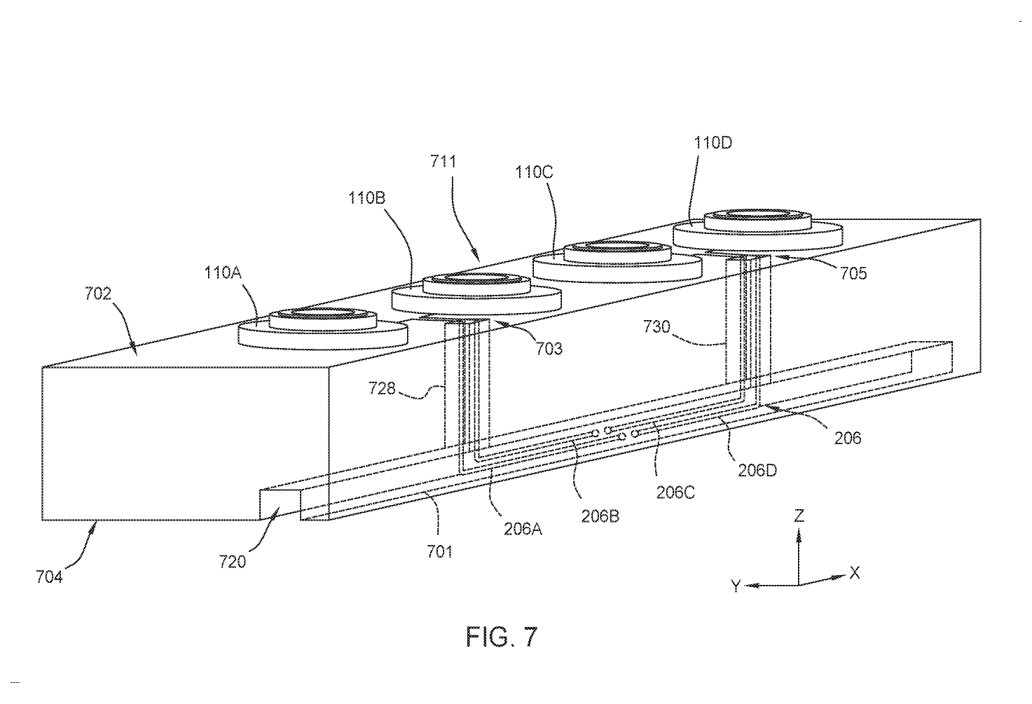

FIG. 7 is a schematic perspective view of a chamber body 711 for a wafer processing system, according to one example embodiment of the present disclosure. In the depicted embodiment of FIG. 7, a trench 720 define by the chamber body 711 is generally defined by a bottom surface 704 of the chamber body 711. In particular, the trench 720 includes a delivery channel 701 extending lengthwise along the first direction X. The transmission lines 206 can extend directly into the delivery channel 701, e.g., from a housing (enclosing the match circuit 202 (FIG. 2) and the splitter circuit 204 (FIG. 2)) arranged beneath the chamber body 711. Once arranged in the delivery channel 701, as represented by the array of circles in FIG. 7, the transmission lines 206 can extend lengthwise along the delivery channel 701, e.g., along the first direction X. The first and second transmission lines 206A, 206B can extend in an opposite direction than the third and fourth transmission lines 206C, 206D in the delivery channel 701.

The first and second transmission lines 206A, 206B can turn and extend upward along a first egress channel 728 defined by the chamber body 711 and the third and fourth transmission lines 206C, 206D can turn and extend upward along a second egress channel 730 defined by the chamber body 711. The first and second egress channels 728, 730 extend lengthwise along the third direction Z and are closed channels, or rather, defined through an interior of the chamber body 711. An opening 703 of the first egress channel 728 at a top surface 702 of the chamber body 711 can be arranged equidistant between the first and second process chambers 110A, 110B, and similarly, an opening 705 of the second egress channel 730 at the top surface 702 can be arranged equidistant between the third and fourth process chambers 110C, 110D. Accordingly, in this example, the trench 720 and the transmission lines 206 can be arranged to have substantially parity or electrical length and can be configured to have a same target characteristic impedance.

In yet other embodiments, the inventive aspects of the present disclosure can apply to wafer processing system having less than four (4) process chambers. An example is provided below.

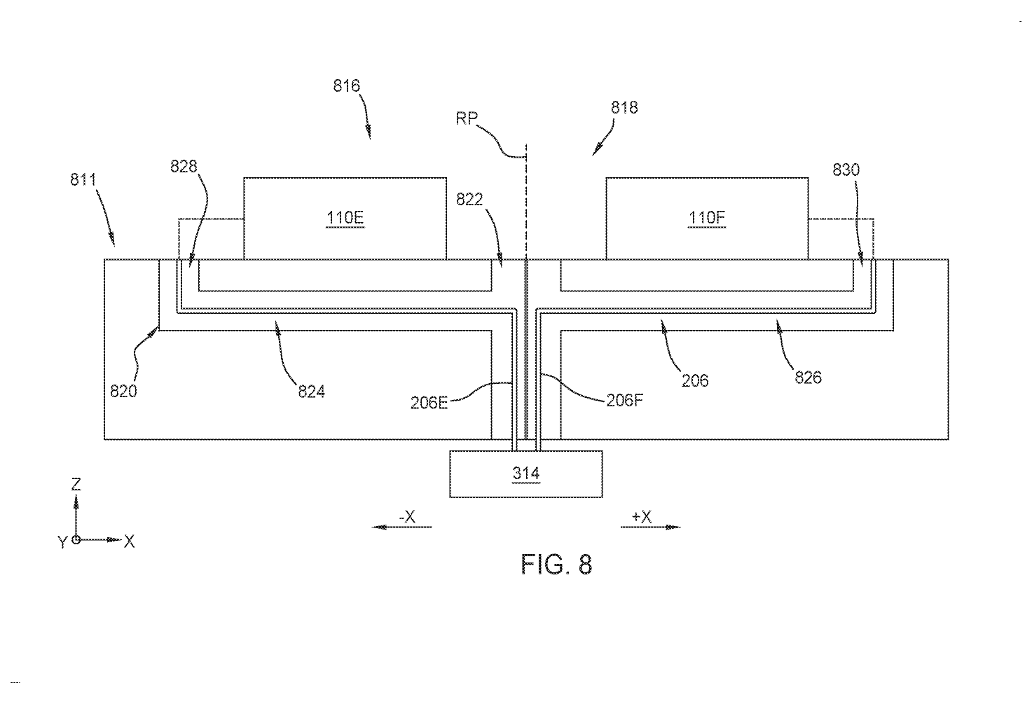

FIG. 8 illustrates a schematic side view of a chamber body 811 for a wafer processing system, according to one example embodiment of the present disclosure. For the depicted embodiment of FIG. 8, the chamber body 811 supports a single process chamber 110E arranged on the first side 816 of a reference plane RP and a single process chamber 110F arranged on the second side 818 of the reference plane RP. A trench 820 defined by a sidewall surface of the chamber body 811 has an ingress channel 822, first and second delivery channels 824, 826, and first and second egress channels 828, 830. The ingress channel 822 is centered along the reference plane RP, e.g., along the first direction X. The first and second delivery channels 824, 826 are in communication with, and extend in opposing directions from, the ingress channel 822. The first egress channel 828 of the trench 820 is in communication with the first delivery channel 824 and the second egress channel 830 of the trench 820 is in communication with the second delivery channel 826. The first and second egress channels 828, 830 are arranged equidistant from the reference plane RP. A transmission line 206E passes through the trench 820 and is electrically coupled with the single process chamber 110E and a transmission line 206F passes through the trench 820 and is electrically coupled with the single process chamber 110F. The trench 820 can be defined and the transmission lines 206E, 206F can be arranged in the trench 820 so that the transmission lines 206E, 206F are arranged in parity. In this way, the transmission lines 206E, 206F can have substantially a same electrical length within the trench 820, which can facilitate the loads of the single process chambers 110E, 110F receiving RF power with matched or substantially matched electrical phase.

While the foregoing is directed to embodiments of the present disclosure, other and further embodiments of the disclosure may be devised without departing from the basic scope thereof, and the scope thereof is determined by the claims that follow.

What is claimed is:

1. A wafer processing system, comprising:
a chamber body arranged to support a plurality of process chambers and defining at least a portion of a trench formed within the chamber body; and
transmission lines disposed within the trench to electrically couple an output of a power supply with respective ones of a plurality of antennas disposed within respective ones of the plurality of process chambers.

2. The wafer processing system of claim 1, wherein the transmission lines are disposed between an output of a splitter circuit and respective ones of the plurality of antennas disposed within respective ones of the plurality of process chambers, and are arranged to have parity with one another so that the transmission lines have substantially a same electrical length between the output of the splitter circuit and respective ones of the plurality of antennas disposed within respective ones of the plurality of process chambers.

3. The wafer processing system of claim 1, wherein the chamber body defines a reference plane, and wherein at least two of the plurality of process chambers are arranged on a first side of the reference plane and at least two of the plurality of process chambers are arranged on a second side of the reference plane, and wherein the transmission lines enter the trench along an ingress channel thereof that is centered on the reference plane.

4. The wafer processing system of claim 1, wherein the transmission lines are configured to have a same target characteristic impedance.

5. The wafer processing system of claim 1, further comprising:
a divider arranged within the trench to separate the trench into a first section and a second section, and wherein a first transmission line of the transmission lines and a second transmission line of the transmission lines are disposed in the first and second sections, respectively.

6. The wafer processing system of claim 5, further comprising:
an access panel mounted to the chamber body so as to enclose the transmission lines within the trench, and is in electrical communication with the chamber body.

7. The wafer processing system of claim 6, wherein the chamber body provides an electrical ground for the transmission lines.

8. The wafer processing system of claim 1, further comprising:
a match circuit arranged to receive electrical current from the power supply; and
a splitter circuit arranged to receive the electrical current from the match circuit, wherein the splitter circuit directs portions of the electrical current from the match circuit to different one of the plurality of process chambers by way of the transmission lines.

9. The wafer processing system of claim 1, wherein the chamber body has a top surface, a bottom surface, and opposing sidewall surfaces, and wherein the trench is defined at least in part by one of the opposing sidewall surfaces.

10. The wafer processing system of claim 1, wherein the chamber body has a top surface, a bottom surface, and opposing sidewall surfaces, and wherein the trench is defined at least in part by the top surface.

11. The wafer processing system of claim 1, wherein the chamber body has a top surface, a bottom surface, and opposing sidewall surfaces, and wherein the trench is defined at least in part by the bottom surface.

12. The wafer processing system of claim 1, wherein the trench has an ingress channel, a first delivery channel and a second delivery channel both in communication with the ingress channel and extending from the ingress channel in opposite directions, and a first egress channel and a second egress channel in communication with the first delivery channel and the second delivery channel, respectively.

13. The wafer processing system of claim 12, wherein at least two transmission lines of the transmission lines pass through the first delivery channel and at least two transmission lines of the transmission lines pass through the second delivery channel.

14. The wafer processing system of claim 12, wherein the chamber body has a top surface and a bottom surface, and wherein the ingress channel extends from the bottom surface toward the top surface so as to communicate with the first and second delivery channels and the first and second egress channels each extend from the top surface toward the bottom surface so as to communicate with the first and second delivery channels.

15. A wafer processing system, comprising:
a chamber body defining a trench and a reference plane;
a plurality of process chambers each held by the chamber body, the plurality of process chambers including a first process chamber, a second process chamber, a third process chamber, and a fourth process chamber, with the first and second process chambers being arranged on a first side of the reference plane and the third and fourth process chambers being arranged on a second side of the reference plane; and
a plurality of transmission lines passing through the trench, the plurality of transmission lines including a first transmission line, a second transmission line, a third transmission line, and a fourth transmission line electrically coupled with the first, second, third, and fourth process chambers, respectively,
wherein the first, second, third, and fourth transmission lines are arranged to have substantial parity within the trench.

16. The wafer processing system of claim 15, wherein the trench has an ingress channel, first and second delivery channels both in communication with the ingress channel and extending from the ingress channel in opposite directions, and first and second egress channels in communication with the first delivery channel and the second delivery channel, respectively,
wherein the first and third transmission lines pass through the ingress channel, the first delivery channel, and the first egress channel, and
wherein the second and fourth transmission lines pass through the ingress channel, the second delivery channel, and the second egress channel.

17. The wafer processing system of claim 16, further comprising:
an ingress channel divider arranged in the ingress channel of the trench and separating the first and third transmission lines from the second and fourth transmission lines.

18. The wafer processing system of claim 16, further comprising at least one of:
a first delivery channel divider arranged in the first delivery channel of the trench and separating the first and third transmission lines along at least a portion of the first delivery channel; or
a second delivery channel divider arranged in the second delivery channel of the trench and separating the second and fourth transmission lines along at least a portion of the second delivery channel.

19. The wafer processing system of claim 16, further comprising at least one of:
a first egress divider arranged in the first egress channel of the trench and separating the first and third transmission lines along at least a portion of the first egress channel; or
a second egress divider arranged in the second egress channel of the trench and separating the second and fourth transmission lines along at least a portion of the second egress channel.

20. A wafer processing system, comprising:
a chamber body defining a trench having an ingress channel, first and second delivery channels in communication with, and extending in opposite directions from, the ingress channel, and first and second egress channels in communication with the first and second delivery channels, respectively;
a plurality of process chambers each held by the chamber body; and
a plurality of transmission lines passing through the trench and being electrically coupled with respective ones of the plurality of process chambers,
wherein each one of the plurality of transmission lines passes through the ingress channel, at least two transmission lines of the plurality of transmission lines pass through the first delivery channel, at least two transmission lines of the plurality of transmission lines pass through the second delivery channel, the at least two transmission lines passing through the first delivery channel exit the trench through the first egress channel, and the at least two transmission lines passing through the second delivery channel exit the trench through the second egress channel.
